(19) United States
(12) Patent Application Publication
(10) Pub. No.: US 2025/0326314 A1
(43) Pub. Date: Oct. 23, 2025

(54) METHODS AND SYSTEMS FOR CHARGING ELECTRIC MACHINES WITH ON-SITE MOBILE CHARGING STATIONS

(71) Applicant: Caterpillar Inc., Peoria, IL (US)

(72) Inventors: Sadia Khalil, Peoria, IL (US); Philippe Tuckmantel, Palo Alto, CA (US); Glen Almgren, Johnstown, CO (US); Roshan Sinha, New York, NY (US); Ruoxi Wu, West Lafayette, IN (US); Deepak Ananthakrishnan, San Ramon, CA (US); Kyaw Linn, West Lafayette, IN (US); Christina Joslin, West Lafayette, IN (US)

(21) Appl. No.: 19/006,740

(22) Filed: Dec. 31, 2024

Related U.S. Application Data
(60) Provisional application No. 63/637,725, filed on Apr. 23, 2024.

(51) Int. Cl. B60L 53/62; B60L 53/63; B60L 53/66; B60L 53/67; B60L 53/68; G01R 31/367

(52) U.S. Cl. CPC B60L 53/62; B60L 53/63; B60L 53/66; B60L 53/67; B60L 53/68; G01R 31/367; B60L 2200/40; B60L 2240/72; B60L 2250/16

(57) ABSTRACT

A technique is directed to methods and systems for managing electric vehicle charging. The electric vehicle management system can determine a battery state of charge using a data driven model and send geolocation push notifications regarding battery charging states to the electric vehicle, operators, and/or fleet managers. The electric vehicle management system can determine the routes for available chargers, the transit time, battery charging time and rate, and peak load costs for a charging an electric vehicle. A user can access the electric vehicle management system via an application on a user device.

### CROSS-REFERENCE TO RELATED APPLICATION

This application claims priority to and the benefit of U.S. Provisional Patent Application No. 63/637,725, filed Apr. 23, 2024, entitled “METHODS AND SYSTEM FOR IMPLEMENTING CHARGE SCHEDULING RECOMMENDATIONS WITHIN A FLEETWIDE NETWORK OF ON-SITE MOBILE CHARGERS,” which is incorporated herein by reference in its entirety.

### BACKGROUND

The transition to electric machines presents unique challenges in managing battery life, optimizing charging infrastructure, and ensuring operational efficiency. Addressing these challenges is crucial for companies to support customer needs and maintain market leadership in the face of customer expectations. The electrification shift introduces complexities in managing electric fleets, particularly in charging logistics and battery performance monitoring. Limited availability of high-fidelity battery data due to the nascent nature of electric machinery in the industry compounds these challenges. Inefficient charging strategies and inadequate battery management can lead to increased downtime for machinery, higher operational costs, and reduced customer satisfaction. These issues directly conflict with most company goals of maximizing value for customers and leading the industry in sustainable progress.

### BRIEF DESCRIPTION OF THE DRAWINGS

FIG. 1 illustrates a data workflow for analyzing charging operations, in accordance with one or more embodiments of the present technology.

FIG. 2A is a flow diagram illustrating a process used in some implementations for predicting state of charge, in accordance with one or more embodiments of the present technology.

FIG. 2B illustrates results of a comparison between machine learning models that predict state of charge, in accordance with one or more embodiments of the present technology.

FIG. 3A is a flow diagram illustrating a process used in some implementations for providing real-time notifications of battery status, in accordance with one or more embodiments of the present technology.

FIG. 3B illustrates a user interface for providing real-time notifications of battery status, in accordance with one or more embodiments of the present technology.

FIG. 4A is a flow diagram illustrating a process used in some implementations for implementing charge scheduling recommendations for on-site mobile charging stations, in accordance with one or more embodiments of the present technology.

FIG. 4B illustrates a network diagram depicting a fleetwide network of on-site charging stations for implementing charge scheduling recommendations, in accordance with one or more embodiments of the present technology.

FIG. 5A is a flow diagram illustrating a process used in some implementations for determining charging schedules for electric vehicles, in accordance with one or more embodiments of the present technology.

FIG. 5B illustrates an example diagram for determining sequences of charging machines, in accordance with one or more embodiments of the present technology.

FIG. 5C illustrates an example diagram for determining sequences of charging machines, in accordance with one or more embodiments of the present technology.

FIG. 6 is a block diagram illustrating an overview of devices on which some implementations can operate.

FIG. 7 is a block diagram illustrating an overview of an environment in which some implementations can operate.

FIG. 8 is a block diagram illustrating components which in some implementations can be used in a system employing the disclosed technology.

The techniques introduced here may be better understood by referring to the following Detailed Description in conjunction with the accompanying drawings, in which like reference numerals indicate identical or functionally similar elements.

### DETAILED DESCRIPTION

Aspects of the present disclosure are directed to methods and systems for determining a management strategy for charging an electric vehicle (EV) fleet. The EV management system can generate data visualizations to determine charging patterns, create a charging sequence to optimize efficiency, and reduce the time an EV wait for a mobile charging stations. The EV management system can determine a battery state of charge using a data driven model and send geolocation push notifications regarding battery charging states to the EV, operators, and/or fleet managers. The EV management system can test algorithms to find the most accurate prediction of a battery's charge level for different levels of energy consumption and generate visual data with the results. Additionally, the EV management system can predict the state of health of the battery based on the results. The EV management system can determine the routes for available chargers, the transit time, battery charging time and rate, and peak load costs for a charging an EV. A user can access the EV management system via an application on a user device.

The EV management system can analyze data on EV usage, determine inferences, and formulate charging operation guidelines that can be customized to each operating center. The EV management system analyzes time series data on the state-of-charge (SOC) on an EV, which is used to predict SOC at any given point of time in future. The EV management system can provide options/suggestions/notifications regarding the charging availability for an EV based on a load optimization algorithm that uses real time data on SOC and physical locations of EVs to optimize charging allocation.

As described in detail below, implementations of the present technology can provide technical advantages over conventional technology. In a first example, the system provides validation of predictive models by successfully demonstrating the accuracy of SoC and state of health (SoH) predictive models. This includes achieving a minimal error margin in predictions which reduces operational downtimes and optimizes charging schedules. In a second example, the system provides an operational efficiency improvement which decreases equipment downtime and increases in the efficiency of charging operations. In a third example, the system provides a cost reduction by achieving a reduction in operational costs related to charging, including lower energy consumption during peak hours through smart scheduling. In a fourth example, the system provides an expansion to other fleet operations, by adapting and scaling the solution to other types of electric fleets, such as transportation, logistics, and personal mobility services. In a fifth example, the system provides a contribution to sustainability goals, by reducing carbon emissions through optimized fleet management and supporting the transition to renewable energy sources.

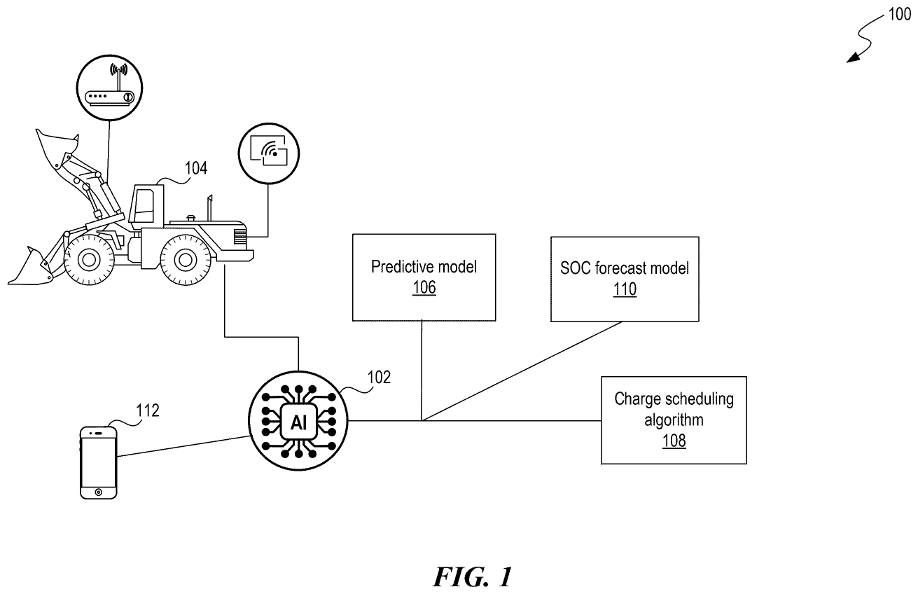

Several implementations are discussed below in more detail in reference to the figures. FIG. 1 illustrates data workflow 100 for analyzing charging operations, in accordance with one or more embodiments of the present technology. The EV management system 102 obtains on-field time series data from the EV fleet 104. In some embodiments, the EV management system collects data from EV charging stations. The EV management system 102 can monitor mobile charging equipment travelling to a location of an EV and performing charging at varying C-rates at varying prices. Using predictive modeling, the EV management system 102 can optimize how to deploy mobile charging equipment to reduce downtown for EVs. Examples of EVs are, but not limited to, construction equipment, mining equipment, bulldozers, excavators, trenchers, loaders, backhoes, compactors, graders, feller bunchers, graders, wheel tractor scrapers, skid-steer loaders, dump trucks, cranes, telehandlers, pavers, and/or pile-driving/boring machines.

The predictive models 106 and charge scheduling algorithms 108 can provide recommendations to a user via an application on a user device 112. The application can provide geospatial push notifications to the user regarding charging alerts, charging options, expected wait times, and expected charge times. The predictive models 106 and charge scheduling algorithms 108 can be trained and retrained with collected EV charging data. The EV management system 102 can determine charge scheduling based on factors, such as geographic location, distance, time, cost, C-rates, varying electricity rates, etc. The EV management system 102 can use a SOC forecast model 110 (e.g., NBEATS, ARIMA, and LSTM) to forecast battery SOC and charger assignments The EV management system 102 can use the charge scheduling algorithm 108 to optimize energy consumption and resource requirements. If a failure is detected, the EV management system 102 can employ backup charging equipment to handle circumstances, such as network failure, sudden increase in demands, or failure of other charging equipment.

The charge scheduling algorithm 108 can serve as the backend of the EV management system by providing charging suggestions and geospatial push notification to users. This optimization can be tested by comparing key performance indicators such as average waiting period, total equipment downtime, total cumulative operation time, total cost of operations etc. To include cost and resource optimization, the EV management system 102 can create a queue system where fleet managers can anticipate/identify the need for charging a particular EV and create a request for mobile charging. By utilizing the predictive models 106, the charge scheduling algorithms 108, and the SOC forecast model 110, and the EV management system 102 can effectively operate with the least number of charging stations. The charging stations can include mobile charging stations and stationary charging stations. The EV management system can identify charging stations and analyze data such as real-time traffic data, road closures, and weather information to determine charge scheduling.

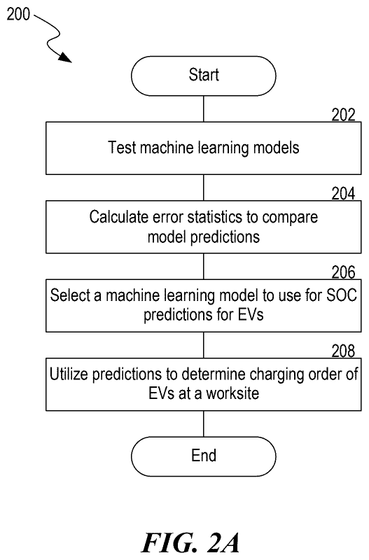

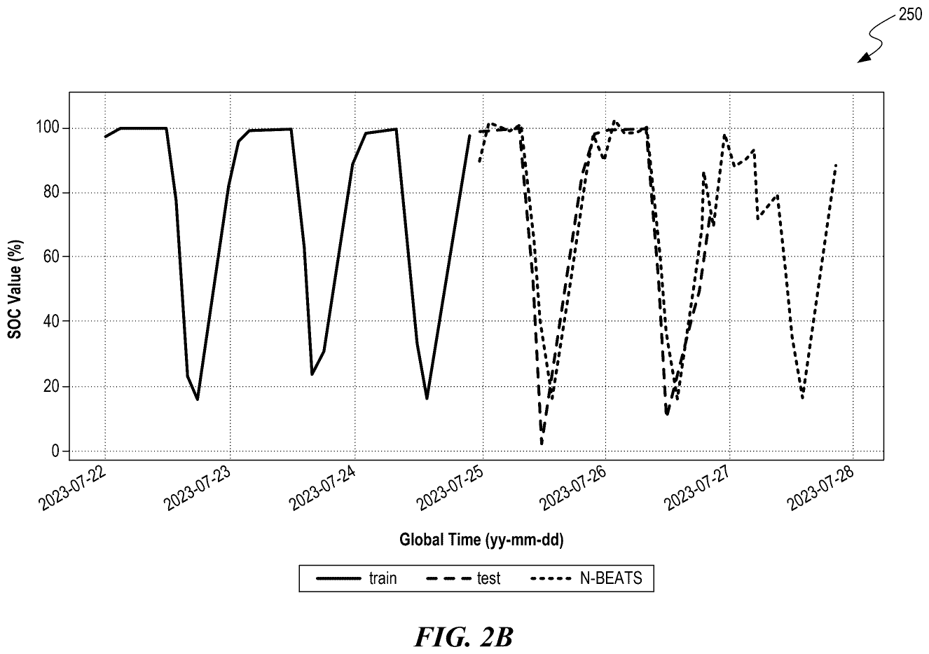

FIG. 2A is a flow diagram illustrating a process 200 used in some implementations for predicting state of charge (SOC), in accordance with one or more embodiments of the present technology. In some implementations, process 200 is triggered by a user activating an EV management application, powering on a device, the user accessing an EV database via a website portal, a machine or device sending data to the EV management system, or the user downloading an application on a device to access the EV management system. In various implementations, some or all of process 200 is performed locally on the user device or performed by cloud-based device(s) that can provide/support the EV management system. The EV management system can predict and forecast the SOC patterns using charging data from electric machinery.

At step 202, the EV management system tests various machine learning models (e.g., Neural Basis Expansion Analysis (NBEATS), Naïve Seasonal Model (Regression Model), and/or Long Short-Term Memory (LSTM)) to determine which model to select for SOC prediction.

At step 204, the EV management system calculates the error statistics for each machine learning model to compare SOC predictions generated by each machine learning model. The models are compared by mean-absolute-error. The EV management system evaluates how each model works against real-world data (e.g., 3 different models based on machine performance).

At step 206, the EV management system selects a machine learning model to use to determine SOC predictions for EVs.

At step 208, the EV management system utilizes the SOC predictions to determine the order to charge EVs at a worksite. The EV management system sends notifications to users at the worksite (e.g., via an application on the user device) to indicate the order to charge the EVs at the worksite. The SOC prediction can prioritize which EV gets priority to a charging station. For example, the battery of an EV operating in wet conditions drains faster than an EV operating in dry conditions. The SOC prediction determines how long the battery will operate before requiring a charge based on historical data, worksite data, weather conditions, type of work, etc.

FIG. 2B illustrates a diagram 250 of results of a comparison between machine learning models that predict SOC (e.g., battery level in voltage), in accordance with one or more embodiments of the present technology. The EV management system can implement a way for an application on a user device to run the algorithm and output the values in a format that the front end can pull from (e.g., JSON file). The EV management system can finish testing new algorithms to find the most accurate prediction of a battery's charge level for different levels of energy consumption. The SOC can include a value for a single battery or multiple batteries of an EV machine. In some embodiments, the EV management system can identify a value of each battery of a machine and perform an aggregate of the multiple batteries.

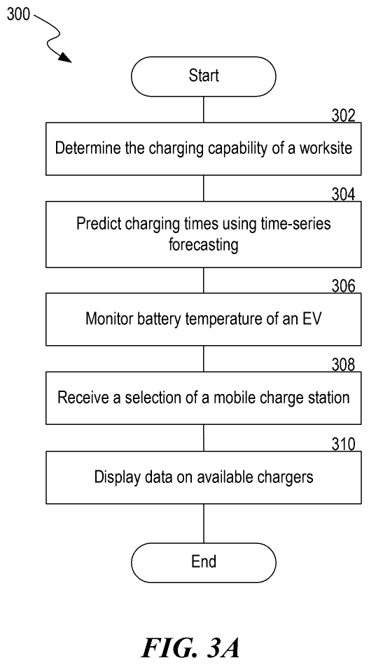

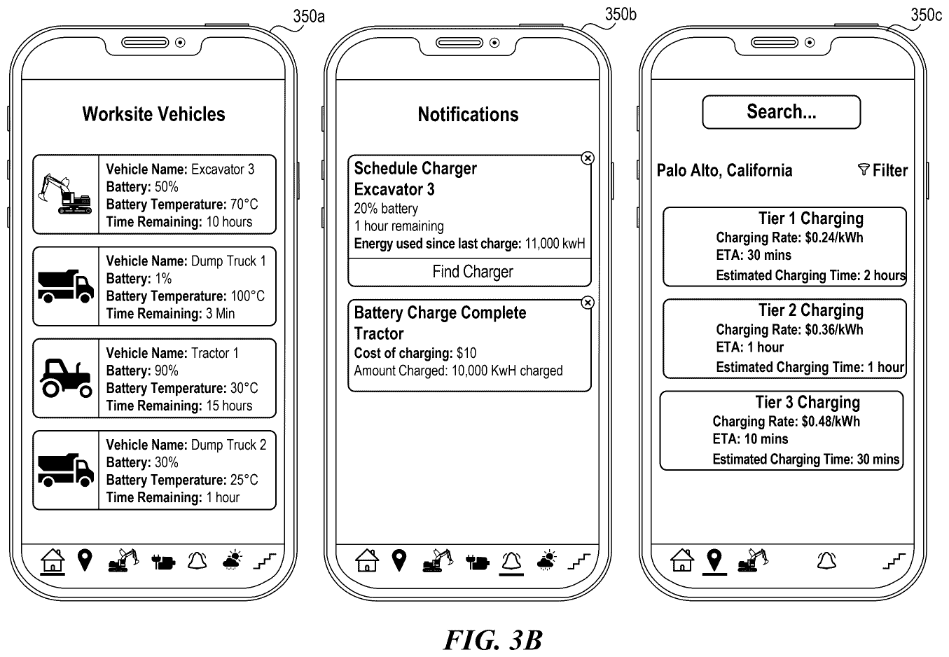

FIG. 3A is a flow diagram illustrating a process 300 used in some implementations for providing real-time notifications of battery status, in accordance with one or more embodiments of the present technology. The system supports productivity and efficiency in EV operations by providing real-time insights into battery status. In some implementations, process 300 is triggered by a user activating an EV management application, powering on a device, the user accessing an EV database via a website portal, EV or device sending data to the EV management system, or the user downloading an application on a device to access the EV management system. In various implementations, some or all of process 300 is performed locally on the user device or performed by cloud-based device(s) that can provide/support the EV management system.

The EV management system allows the fleet managers to monitor and manage their worksite vehicles. At step 302, the EV management system determines the charging capability of a worksite, such as the number of mobile charging stations in a geographic region. The EV management system can evaluate the number and types of charging stations available, power output capabilities of the charging stations, and the distribution of the charging stations across the worksite. The system may also consider the electrical infrastructure of the site, including the available power supply, transformer capacity, and any limitations on peak power consumption. Additionally, the EV management system analyzes the physical layout of the worksite, identifying potential bottlenecks or areas where charging stations can be placed to maximize accessibility and minimize disruption to worksite operations.

In some cases, the EV management system may utilize historical data and predictive analytics to determine the optimal charging capability for a worksite. This may involve analyzing patterns of EV usage, typical work schedules, and seasonal variations in power demand. The system may also consider future expansion plans, potential increases in the EV fleet size, and anticipated changes in workload that could impact charging requirements. Additionally, the EV management system can determine distances between EVs and mobile charging stations and determine travel times for the mobile charging stations to reach an EV location.

At step 304, the EV management system predicts charging times using time-series forecasting. This prediction process may take into account various factors such as historical charging data, current battery state of charge, environmental conditions, and usage patterns of the EVs. By analyzing these diverse data points, the system can generate accurate estimates of when an EV will need a charge and how long it may take to charge an EV from its current state to a desired level of charge.

In some cases, the EV management system may utilize machine learning algorithms to continuously improve its charging time predictions. As the system collects data from actual charging sessions, it can refine its forecasting models to account for factors such as battery degradation over time, variations in charging efficiency under different conditions, and the impact of fast charging versus slow charging on overall charging times. This adaptive approach allows the system to provide increasingly accurate predictions, which can help in reducing downtime, improving charging station utilization, and enhancing overall fleet efficiency. Based on the predicted charging times, the EV management system generates and notifies users of the time remaining before the EV machine hits battery threshold (e.g., 15% of full capacity, or any amount) or the battery runs out of power.

At step 306, the EV management system monitors the temperature of a battery an EV. The EV management system can send a user a notification when the temperature of the battery reaches a threshold level. At step 308, the EV management system receives a selection of a mobile charging station to charge an EV. A user can select the charging station via an application on a user device.

At step 310, the EV management system displays various data on the mobile charging stations, such as charging rates and the estimated time before the charger arrives at the worksite. The EV management system can integrate with SoC forecasting and charge scheduling.

FIG. 3B illustrates a user interface 350 for providing real-time notifications of battery status, in accordance with one or more embodiments of the present technology. A user can access the EV management system via an application displayed in user interface 350 of a user device. The user interface 350 can display notifications, such as temperature high, temp low, battery low, time until charge is complete, time until battery is drained, type of error, serial number, temperature number, or battery percentage. The user interface 350 can display a login page of an application to access the EV management system. The user interface 350 can include a charger page with the location and charging rate of EV chargers. The user interface 350 is designed to provide comprehensive information about EV fleet management, allowing users to monitor vehicle status, receive notifications, and make informed decisions about charging operations.

User interface 350a displays a worksite vehicles section that displays information about multiple vehicles at a worksite. Each vehicle entry includes details such as the vehicle name, battery percentage, battery temperature, and remaining operating time. Icons representing different vehicle types are shown alongside each entry. User interface 350b displays a notifications section that provides alerts related to charging operations. The notifications include information about a scheduled charger, battery percentage of an EV, remaining charge time, and energy usage since the last charge. Additionally, user interface 350b displays a notification about a completed battery charge, including the cost of charging and the amount of energy charged. User interface 350c displays a charging recommendation section with tiered charging options. Each tier shows the charging rate in kWh, estimated charging time, and other relevant details.

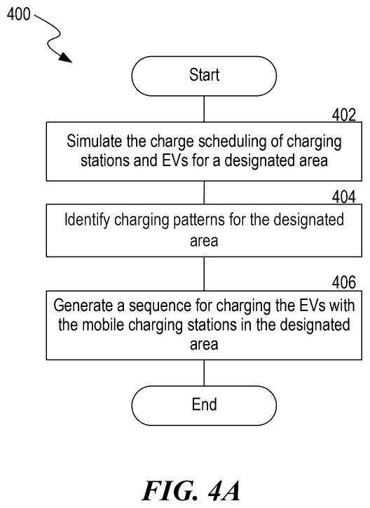

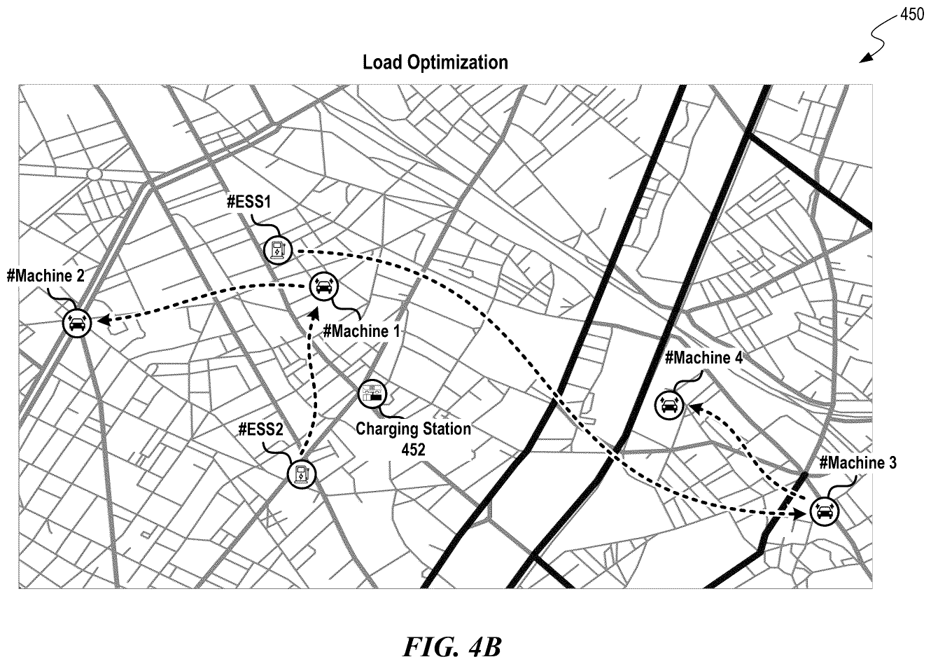

FIG. 4A is a flow diagram illustrating a process for implementing charge scheduling recommendations for on-site mobile charging stations, in accordance with one or more embodiments of the present technology. In some implementations, process 400 is triggered by a user activating an EV management application, powering on a device, the user accessing an EV database via a website portal, a machine or device sending data to the EV management system, or the user downloading an application on a device to access the EV management system. In various implementations, some or all of process 400 is performed locally on the user device or performed by cloud-based device(s) that can provide/support the EV management system.

At step 402, the EV management system can simulate the charge scheduling of charging stations and EVs for a designated area using charging station data. The EV management system may simulate charge scheduling by creating a virtual environment that replicates the real-world conditions of a designated area. This simulation may incorporate various factors such as the number and types of EVs, current state of charge, usage patterns, and the availability and capabilities of charging stations. The system may use historical data and predictive models to estimate how the EVs' charge levels will change over time based on their expected usage. It may also factor in the characteristics of different charging stations, including their charging speeds, locations, and availability windows.

In some cases, the simulation may run multiple scenarios with different charging strategies. These scenarios may vary factors such as the order in which EVs are charged, the allocation of mobile charging stations, and the timing of charging sessions. The system may evaluate each scenario based on metrics such as total charging time, energy efficiency, cost, and impact on EV availability. By running these simulations, the EV management system can identify optimal charging schedules that balance the needs of the entire fleet while considering constraints such as peak electricity rates, charging station capacity, and EV operational requirements. The EV management system can generate a dataset of the simulations results for the designated area. Based on the simulations results, the EV management system can manage an EV fleet.

At step 404, the EV management system identifies charging patterns for the designated area. The EV management system may identify charging patterns for a designated area by analyzing historical and real-time data collected from the EVs and charging stations within that area. This analysis may include examining factors such as the frequency of charging sessions, duration of charges, times of day when charging typically occurs, and the types of EVs that commonly use the charging stations. The system may also consider the specific tasks performed by the EVs in the area, such as loading or digging, and correlate these activities with their impact on battery consumption and charging needs. By processing this data, the EV management system can recognize recurring patterns and trends in charging behavior, which may vary based on the time of day, day of the week, or seasonal factors.

In some cases, the EV management system may employ advanced data analytics and machine learning algorithms to detect charging patterns. These algorithms may identify relationships between various factors such as weather conditions, workload intensity, and charging behavior. For instance, the system might recognize that certain types of EVs tend to require more frequent charging during hot weather or when engaged in particularly energy-intensive tasks. By continuously updating and refining its understanding of these patterns, the EV management system can adapt its charging recommendations and scheduling strategies to better align with the actual usage patterns and needs of the EVs in the designated area, potentially improving overall efficiency and reducing downtime. The EV management system generates visualized data to illustrate the identified charging patterns (as shown in FIG. 4B).

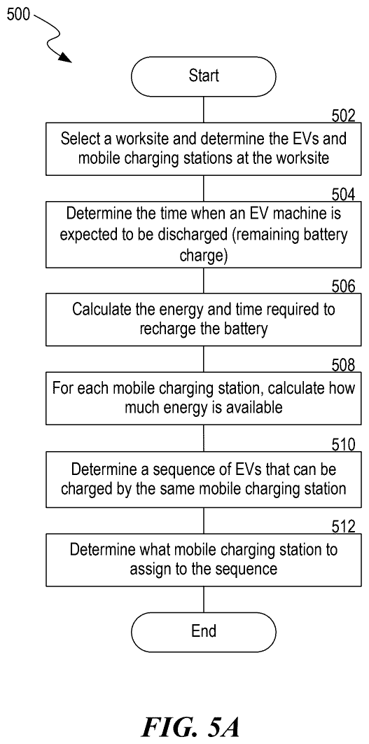

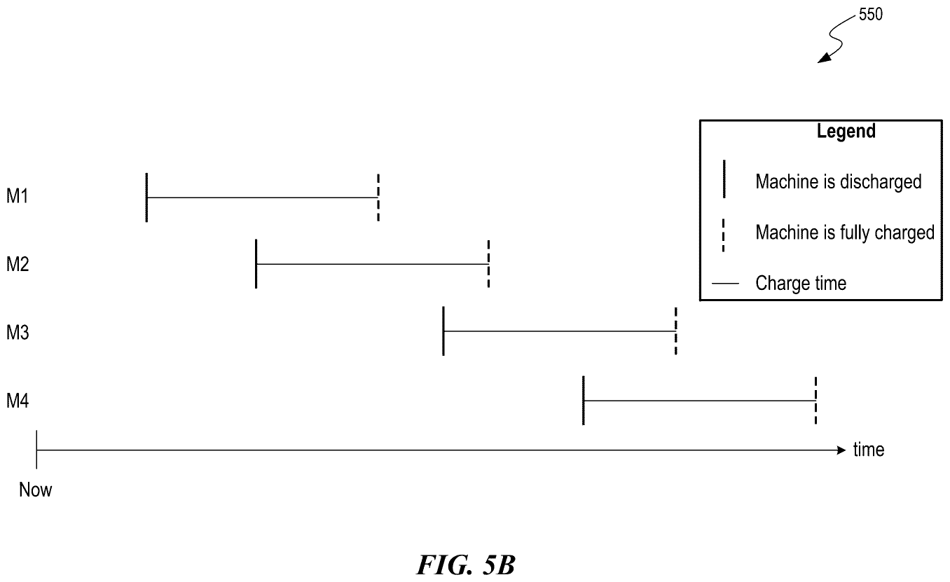

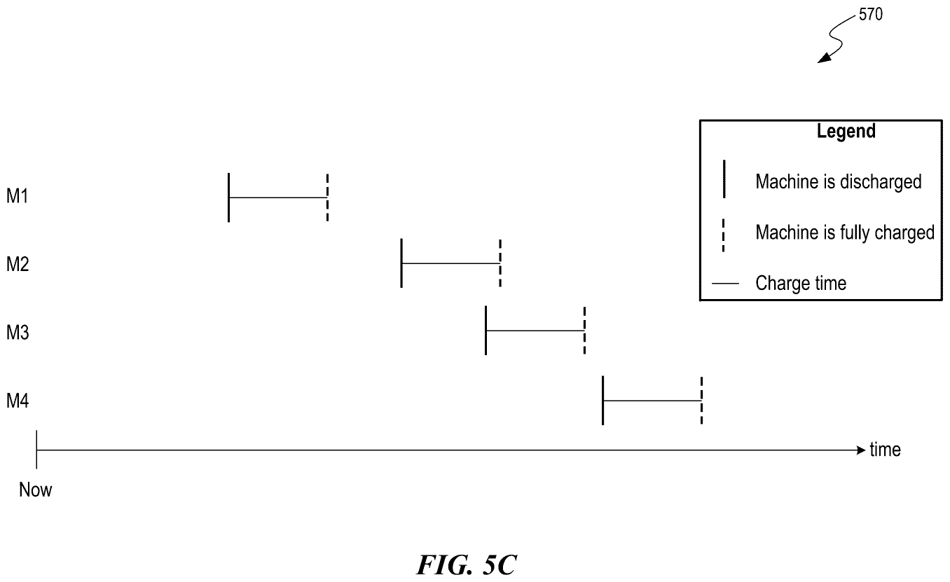

At step 406, the EV management system generates a sequence for charging the EVs with the mobile charging stations in the designated area based on the identified patterns and mobile charging station availability. The EV management system can generate guidelines for optimizing efficiency and reducing the wait time between the EVs and the mobile charging stations. Additional detail for sequence generation are provided in FIGS. 5A, 5B, and 5C.

FIG. 4B illustrates a network diagram 450 depicting a fleetwide network of on-site mobile charging stations for implementing charge scheduling recommendations, in accordance with one or more embodiments of the present technology. The network diagram 450 shows a map layout with various components representing machines, charging stations, and mobile charging stations. The network diagram 450 includes machine 1, machine 2, machine 3, and machine 4 distributed across the map. These machines represent the EVs or equipment that require charging. A charging station 452 is depicted on the map, which serves as a fixed charging point for the fleet. Two mobile charging stations, labeled as ESS1 and ESS2, are shown on the diagram. These mobile charging stations represent Energy Storage Systems (ESS) that can move to different locations to charge the machines. The layout of the network diagram 450 resembles a road or street map, with lines representing possible paths for the mobile charging stations to travel to and from the EVs. The network diagram 450 illustrates a dynamic charging system where mobile charging stations ESS1 and ESS2 can be dispatched to different machines 1-4 as needed. This setup allows for flexible charging operations across the fleet, optimizing the use of mobile charging resources.

FIG. 5A is a flow diagram illustrating a process for determining charging schedules for electric vehicles, in accordance with one or more embodiments of the present technology. The system supports productivity and efficiency in EV operations by providing real-time insights into battery status. In some implementations, process 500 is triggered by a user activating an EV management application, powering on a device, the user accessing an EV database via a website portal, a machine or device sending data to the EV management system, or the user downloading an application on a device to access the EV management system. In various implementations, some or all of process 500 is performed locally on the user device or performed by cloud-based device(s) that can provide/support the EV management system. The terms “ESS” and “mobile charging station” are used interchangeably.

The EV management system can determine how to charge the most machines with the minimum number of mobile charging stations by determining a prioritization order of the machines. The EV management system can determine when each of the EVs needs to be charged. The EV management system determines how much charging capability is required to get an EV to full capacity based on the battery capacity of each EV and the current battery value of the EV. The EV management can determine the timeline of charging each machine.

At step 502, the EV management system selects a worksite and determines the EVs and mobile charging stations at the worksite.

At step 504, the EV management system determines the time when an EV is expected to be discharged (e.g., when the SOC value reaches a threshold). The determine time may be based on a combination of historical data, real-time monitoring, and predictive modeling. The system may analyze past usage patterns of each EV, taking into account factors such as typical daily operations, energy consumption rates during different tasks, and environmental conditions that may affect battery performance. By integrating this historical data with real-time information about the EV's current SOC, ongoing tasks, and operational schedule, the system can estimate the remaining operational time before the battery reaches a predefined threshold charge.

In some cases, the EV management system may utilize machine learning algorithms to enhance the accuracy of discharge time predictions. These algorithms may consider additional variables such as weather forecasts, terrain conditions, and even driver behavior patterns to refine the estimates. The system may continuously update its predictions as new data becomes available, allowing for dynamic adjustments to charging schedules. The EV management system can organize the EVs based on the amount of operation time each EV has before reaching the SOC threshold.

At step 506, the EV management system calculates the energy and time required to recharge (e.g., charge a battery to a threshold level, such as 90%, 100%, or any value) the battery of an EV. The EV management system can calculate the energy and time required to recharge an EV battery based on the current SOC of the battery, the target SOC, the battery's capacity, and the charging rate of the available charging station. The system may use a combination of manufacturer-provided specifications and historical charging data to estimate the energy needed. For instance, if an EV's battery has a capacity of 100 kWh and is currently at 20% SOC, with a target of 80% SOC, the system may calculate that approximately 60 kWh of energy is required for the recharge.

The time required for recharging may be estimated based on the calculated energy requirement and the charging rate of the available charging station. The EV management system may take into account that charging rates can vary depending on the SOC, with faster charging typically occurring at lower SOC levels and slowing down as the battery approaches full charge. Environmental factors such as temperature may also be considered, as they can affect charging efficiency. The system may use this information to provide a more accurate estimate of charging time, which can be crucial for optimizing the charging schedule across the fleet and minimizing downtime for individual EVs.

At step 508, the EV management system, for each ESS, calculates how much energy the ESS has available to charge an EV battery. The EV management system may calculate the available energy in each ESS based on the total capacity of the ESS, the current state of charge, and any energy losses that might occur during the charging process. The system may also take into account the ESS's charging and discharging efficiency rates, which can vary depending on environmental conditions and the age of the equipment. By analyzing historical data on the ESS's performance and real-time monitoring of its status, the EV management system can provide an estimate of the energy available for charging EVs.

In some cases, the EV management system may employ predictive algorithms to anticipate how much energy the ESS will have available at different points in time. This prediction may consider factors such as scheduled charging times for the ESS itself, expected energy consumption patterns based on historical data, and any planned maintenance that might affect the ESS's capacity. The system may also factor in the potential for energy regeneration in cases where the ESS can capture and store energy from other sources, such as solar panels or regenerative braking systems on EVs. The EV management system can determine how many EVs each ESS can charge based on the charging capability of the ESS.

The EV management system can create a charging timeline for each machine, based on a charging starting in response to an EV's SOC reaching a threshold value (e.g. percentage or charge value). This value can be user-defined or derived through a statistical model. The EV management system can use this timeline to automatically determine which EVs can be charged in sequence by the same ESS.

At step 510, the EV management system determines a sequence of EVs that can be charged by the same ESS. In a first example, as shown in diagram 550 of FIG. 5B, EVs (M1 and M2) cannot be charged by the same ESS because M2 will be depleted before M1 is finished charging. In a second example, diagram 550 of FIG. 5B illustrates two charging sequences: [M1, M3] and [M2, M4]. In a third example, diagram 570 of FIG. 5C illustrates multiple sequences, with different maximum lengths, such as:
Max 3: {[M1, M2, M4], [M3]} or {[M1, M3, M4], [M2]}
Max 2: {[M1, M2], [M3, M4]} or {[M1, M3], [M2, M4]}

In some cases, the EV management system assigns one ESS per sequence. In some cases, the EV management system assigns an ESS for multiple sequences. In some case, the EV management system selects longer sequences over shorter sequences to maximize the usage of some ESSs, while keeping other ESSs available for unplanned issues at the worksite. The EV management system can determine the longest possible sequence of non-overlapping EV charges. In diagram 550 of FIG. 5B, for example, there are two sequences of length 2 ([M1, M3], [M2, M4]). In diagram 570 of FIG. 5C, there are 2 possibilities for sequences with length 3 ([M1, M2, M4]) or {[M1, M3, M4]). Once the EV management system has determined the longest sequence allowed by each ESS and battery capacity, the EV management system determines the longest non-overlapping sequence among the remaining EVs. The process can be repeated until all the EVs are in a sequence.

At step 512, the EV management system determines what ESS to assign to the determined sequence(s). AN ESS can be selected based on the having the capability to charge each EV in the sequence. For example, for each generated sequence, the EV management system determines which ESS has enough energy to charge all the EVs in the sequence. Once an ESS is assigned to a sequence, the assigned ESS is removed from the pool of available ESSs. If there are multiple ESSs with the ability to complete a charging sequence, the EV management system can select the ESS with the lowest SoC and assign it to the charging sequence. If a charging sequence of EV cannot be completed by any available ESS, the EV management system can remove the one or more EVs from the sequence. The removed EVs can be added to another sequence. The sequencing assignment process is repeated until every EV is charged or the ESSs are depleted and unable to charge an EV.

FIG. 5B illustrates an example diagram 550 for determining sequences of charging machines, in accordance with one or more embodiments of the present technology. The EV system determines the order the machines can be charged one after the other. The charging sequence diagram 550 shows the discharge and charge timelines for four EVs labeled M1, M2, M3, and M4 along a vertical time axis. A legend is provided in the upper left corner of the diagram, indicating solid lines represent when an EV is discharged, dashed lines represent when a machine is fully charged, and thin solid lines represent charge time. The diagram illustrates the staggered discharge and charge cycles of the four machines, with M1 discharging first, followed by M2, M3, and M4. The charge times for each EV are shown as vertical lines connecting the discharge and fully charged states.

FIG. 5C illustrates an example diagram 570 for determining sequences of charging machines, in accordance with one or more embodiments of the present technology. The charging sequence diagram 570 shows the charging timelines for four EVs labeled M1, M2, M3, and M4 along a vertical time axis. Each EV's timeline is represented by a combination of solid and dashed lines, where solid lines indicate when a machine is discharged and dashed lines represent the charging time. The diagram includes a legend that explains the line styles: solid lines for when an EV is discharged, dashed lines for when an EV is fully charged, and thin solid lines for the charge time. The charging sequences for each EV are staggered, allowing for efficient use of charging resources across the fleet over time.

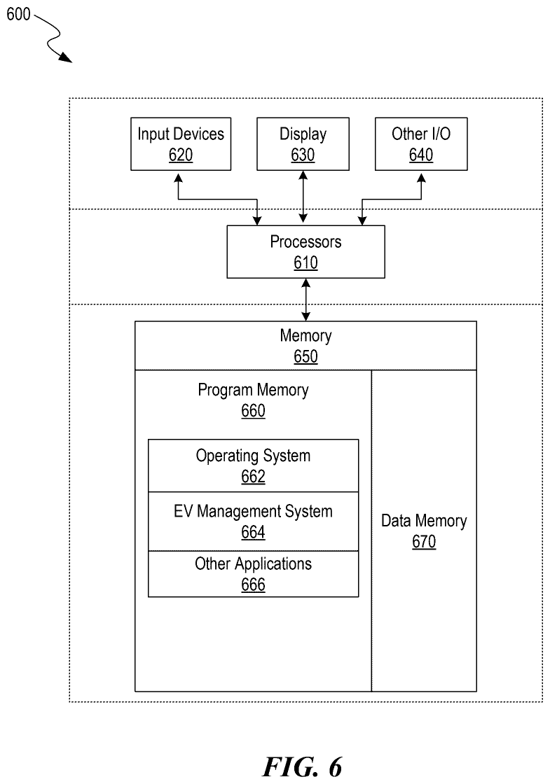

FIG. 6 is a block diagram illustrating an overview of devices on which some implementations of the disclosed technology can operate. The devices can comprise hardware components of a device 600 that manage entitlements within a real-time telemetry system. Device 600 can include one or more input devices 620 that provide input to the processor(s) 610 (e.g., CPU(s), GPU(s), HPU(s), etc.), notifying it of actions. The actions can be mediated by a hardware controller that interprets the signals received from the input device and communicates the information to the processors 610 using a communication protocol. Input devices 620 include, for example, a mouse, a keyboard, a touchscreen, an infrared sensor, a touchpad, a wearable input device, a camera- or image-based input device, a microphone, or other user input devices.

Processors 610 can be a single processing unit or multiple processing units in a device or distributed across multiple devices. Processors 610 can be coupled to other hardware devices, for example, with the use of a bus, such as a PCI bus or SCSI bus. The processors 610 can communicate with a hardware controller for devices, such as for a display 630. Display 630 can be used to display text and graphics. In some implementations, display 630 provides graphical and textual visual feedback to a user. In some implementations, display 630 includes the input device as part of the display, such as when the input device is a touchscreen or is equipped with an eye direction monitoring system. In some implementations, the display is separate from the input device. Examples of display devices are: an LCD display screen, an LED display screen, a projected, holographic, or augmented reality display (such as a heads-up display device or a head-mounted device), and so on. Other I/O devices 640 can also be coupled to the processor, such as a network card, video card, audio card, USB, firewire or other external device, camera, printer, speakers, CD-ROM drive, DVD drive, disk drive, or Blu-Ray device.

In some implementations, the device 600 also includes a communication device capable of communicating wirelessly or wire-based with a network node. The communication device can communicate with another device or a server through a network using, for example, TCP/IP protocols. Device 600 can utilize the communication device to distribute operations across multiple network devices.

The processors 610 can have access to a memory 650 in a device or distributed across multiple devices. A memory includes one or more of various hardware devices for volatile and non-volatile storage, and can include both read-only and writable memory. For example, a memory can comprise random access memory (RAM), various caches, CPU registers, read-only memory (ROM), and writable non-volatile memory, such as flash memory, hard drives, floppy disks, CDs, DVDs, magnetic storage devices, tape drives, and so forth. A memory is not a propagating signal divorced from underlying hardware; a memory is thus non-transitory. Memory 650 can include program memory 660 that stores programs and software, such as an operating system 662, EV management system 664, and other application programs 666. Memory 650 can also include data memory 670, storing as telematics device data, radio device data, SIM card data, telematics package, product data (e.g., machine type), subscription data, dealer/customer data, location data, asset health data, electronic control module (ECM) data, diagnostic trouble code (DTC) data, lifetime total measure data, daily delta data, quality rule data, telemetry (e.g., message level) data, or any criteria associated with an asset, configuration data, settings, user options or preferences, etc., which can be provided to the program memory 660 or any element of the device 600.

Some implementations can be operational with numerous other computing system environments or configurations. Examples of computing systems, environments, and/or configurations that may be suitable for use with the technology include, but are not limited to, personal computers, server computers, handheld or laptop devices, cellular telephones, wearable electronics, gaming consoles, tablet devices, multiprocessor systems, microprocessor-based systems, set-top boxes, programmable consumer electronics, network PCs, minicomputers, mainframe computers, distributed computing environments that include any of the above systems or devices, or the like.

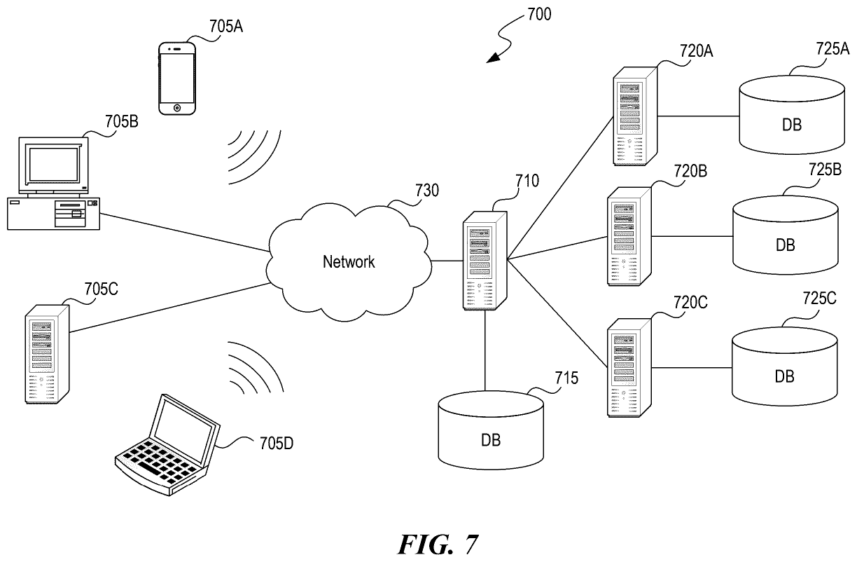

FIG. 7 is a block diagram illustrating an overview of an environment 700 in which some implementations of the disclosed technology can operate. Environment 700 can include one or more client computing devices 705A-D, examples of which can include device 600. Client computing devices 705 can operate in a networked environment using logical connections through network 730 to one or more remote computers, such as a server computing device 710.

In some implementations, server 710 can be an edge server which receives client requests and coordinates fulfillment of those requests through other servers, such as servers 720A-C. Server computing devices 710 and 720 can comprise computing systems, such as device 600. Though each server computing device 710 and 720 is displayed logically as a single server, server computing devices can each be a distributed computing environment encompassing multiple computing devices located at the same or at geographically disparate physical locations. In some implementations, each server 720 corresponds to a group of servers.

Client computing devices 705 and server computing devices 710 and 720 can each act as a server or client to other server/client devices. Server 710 can connect to a database 715. Servers 720A-C can each connect to a corresponding database 725A-C. As discussed above, each server 720 can correspond to a group of servers, and each of these servers can share a database or can have their own database. Databases 715 and 725 can warehouse (e.g., store) information such as implement data, machine data, sensor data, device data, notification data, as telematics device data, radio device data, SIM card data, telematics package, product data (e.g., machine type), subscription data, dealer/customer data, location data, asset health data, electronic control module (ECM) data, diagnostic trouble code (DTC) data, lifetime total measure data, daily delta data, quality rule data, telemetry (e.g., message level) data, or any criteria associated with an asset. Though databases 715 and 725 are displayed logically as single units, databases 715 and 725 can each be a distributed computing environment encompassing multiple computing devices, can be located within their corresponding server, or can be located at the same or at geographically disparate physical locations.

Network 730 can be a local area network (LAN) or a wide area network (WAN), but can also be other wired or wireless networks. Network 730 may be the Internet or some other public or private network. Client computing devices 705 can be connected to network 730 through a network interface, such as by wired or wireless communication. While the connections between server 710 and servers 720 are shown as separate connections, these connections can be any kind of local, wide area, wired, or wireless network, including network 730 or a separate public or private network.

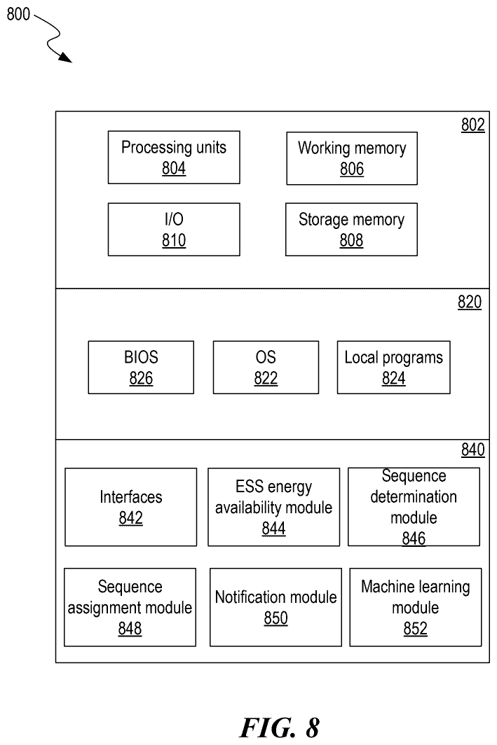

FIG. 8 is a block diagram illustrating components 800 which, in some implementations, can be used in a system employing the disclosed technology. The components 800 include hardware 802, general software 820, and specialized components 840. As discussed above, a system implementing the disclosed technology can use various hardware including processing units 804 (e.g. CPUs, GPUs, APUs, etc.), working memory 806, storage memory 808 (local storage or as an interface to remote storage, such as storage 715 or 725), and input and output devices 810. In various implementations, storage memory 808 can be one or more of: local devices, interfaces to remote storage devices, or combinations thereof. For example, storage memory 808 can be a set of one or more hard drives (e.g. a redundant array of independent disks (RAID)) accessible through a system bus or can be a cloud storage provider or other network storage accessible via one or more communications networks (e.g. a network accessible storage (NAS) device, such as storage 715 or storage provided through another server 720). Components 800 can be implemented in a client computing device such as client computing devices 705 or on a server computing device, such as server computing device 710 or 720.

General software 820 can include various applications including an operating system 822, local programs 824, and a basic input output system (BIOS) 826. Specialized components 840 can be subcomponents of a general software application 820, such as local programs 824. Specialized components 840 can include ESS energy availability module 844, sequence determination module 846, sequence assignment module 848, notification module 850, machine learning module 852, and components which can be used for providing user interfaces, transferring data, and controlling the specialized components, such as interfaces 842. In some implementations, components 800 can be in a computing system that is distributed across multiple computing devices or can be an interface to a server-based application executing one or more of specialized components 840. Although depicted as separate components, specialized components 840 may be logical or other nonphysical differentiations of functions and/or may be submodules or code-blocks of one or more applications.

In some implementations, the ESS energy availability module 844, sequence determination module 846, sequence assignment module 848, notification module 850, machine learning module 852, are configured to perform any of the steps of process 200, 300, 400, or 500.

Those skilled in the art will appreciate that the components illustrated in FIGS. 6-8 described above, and in each of the flow diagrams discussed below, may be altered in a variety of ways. For example, the order of the logic may be rearranged, substeps may be performed in parallel, illustrated logic may be omitted, other logic may be included, etc. In some implementations, one or more of the components described above can execute one or more of the processes described below.

### INDUSTRIAL APPLICABILITY

The systems and methods described herein can using electric vehicle (EV) charging station data to determine a management strategy for charging an electric vehicle (EV) fleet. The EV management system can generate data visualizations to determine charging patterns, create a charging sequence to optimize efficiency, and reduce the time an EV wait for a mobile charging stations. The EV management system can determine a battery state of charge using a data driven model and send geolocation push notifications regarding battery charging states to the EV, operators, and/or fleet managers. The EV management system can test algorithms to find the most accurate prediction of a battery's charge level for different levels of energy consumption and generate visual data with the results. Additionally, the EV management system can predict the state of health of the battery based on the results. The EV management system can determine the routes for available chargers, the transit time, battery charging time and rate, and peak load costs for a charging an EV. A user can access the EV management system via an application on a user device.

The EV management system can analyze data on EV usage, determine inferences, and formulate charging operation guidelines that can be customized to each operating center. The EV management system analyzes time series data on the state-of-charge (SOC) on an EV, which is used to predict SOC at any given point of time in future. The EV management system can provide options/suggestions/notifications regarding the charging availability for an EV based on a load optimization algorithm that uses real time data on SOC and physical locations of EVs to optimize charging allocation. The present systems and methods can be implemented to manage and control, multiple industrial machines, vehicles and/or other suitable devices such as mining machines, trucks, corporate fleets, etc.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

Reference in this specification to “implementations” (e.g. “some implementations,” “various implementations,” “one implementation,” “an implementation,” etc.) means that a particular feature, structure, or characteristic described in connection with the implementation is included in at least one implementation of the disclosure. The appearances of these phrases in various places in the specification are not necessarily all referring to the same implementation, nor are separate or alternative implementations mutually exclusive of other implementations. Moreover, various features are described which may be exhibited by some implementations and not by others. Similarly, various requirements are described which may be requirements for some implementations but not for other implementations.

As used herein, being above a threshold means that a value for an item under comparison is above a specified other value, that an item under comparison is among a certain specified number of items with the largest value, or that an item under comparison has a value within a specified top percentage value. As used herein, being below a threshold means that a value for an item under comparison is below a specified other value, that an item under comparison is among a certain specified number of items with the smallest value, or that an item under comparison has a value within a specified bottom percentage value. As used herein, being within a threshold means that a value for an item under comparison is between two specified other values, that an item under comparison is among a middle-specified number of items, or that an item under comparison has a value within a middle-specified percentage range. Relative terms, such as high or unimportant, when not otherwise defined, can be understood as assigning a value and determining how that value compares to an established threshold. For example, the phrase “selecting a fast connection” can be understood to mean selecting a connection that has a value assigned corresponding to its connection speed that is above a threshold.

Unless explicitly excluded, the use of the singular to describe a component, structure, or operation does not exclude the use of plural such components, structures, or operations. As used herein, the word “or” refers to any possible permutation of a set of items. For example, the phrase “A, B, or C” refers to at least one of A, B, C, or any combination thereof, such as any of: A; B; C; A and B; A and C; B and C; A, B, and C; or multiple of any item such as A and A; B, B, and C; A, A, B, C, and C; etc.

As used herein, the expression “at least one of A, B, and C” is intended to cover all permutations of A, B and C. For example, that expression covers the presentation of at least one A, the presentation of at least one B, the presentation of at least one C, the presentation of at least one A and at least one B, the presentation of at least one A and at least one C, the presentation of at least one B and at least one C, and the presentation of at least one A and at least one B and at least one C.

Although the subject matter has been described in language specific to structural features and/or methodological acts, it is to be understood that the subject matter defined in the appended claims is not necessarily limited to the specific features or acts described above. Specific embodiments and implementations have been described herein for purposes of illustration, but various modifications can be made without deviating from the scope of the embodiments and implementations. The specific features and acts described above are disclosed as example forms of implementing the claims that follow. Accordingly, the embodiments and implementations are not limited except as by the appended claims.

Any patents, patent applications, and other references noted above are incorporated herein by reference. Aspects can be modified, if necessary, to employ the systems, functions, and concepts of the various references described above to provide yet further implementations. If statements or subject matter in a document incorporated by reference conflicts with statements or subject matter of this application, then this application shall control.

I/We claim:

1. A method of managing electric vehicle charging, the method comprising:
receiving state of charge values for respective batteries of a plurality of electric vehicles at a worksite;
determining respective charging times required to charge the respective batteries to a threshold value based on the state of charge values;
calculating a charging capability of at least one mobile charging station at the worksite;
generating a charging sequence for the plurality of electric vehicles based on the respective charging times and the charging capability of the at least one mobile charging station; and
assigning the at least one mobile charging station to the charging sequence.

2. The method of claim 1, further comprising:
sending a notification to the plurality of electric vehicles, wherein the notification includes, for each electric vehicle, a place in the charging sequence, a battery status, a battery temperature, and time remaining until requiring a charge.

3. The method of claim 1, further comprising:
determining a charging rate of the at least one mobile charging station;
determining energy losses during charging operations of the at least one mobile charging station;
determining a current state of charge of the at least one mobile charging station; and
calculating the charging capability of the at least one mobile charging station based on the charging rate, the energy losses, and the current state of charge.

4. The method of claim 1, further comprising:
inputting, into a machine learning model, historical usage data for an electric vehicle of the plurality of electric vehicles for a task being performed by the electric vehicle;
determining, by the machine learning model, a predicted energy consumption rate while the electric vehicle performs the task;
calculating, by the machine learning model, a projected state of charge for the electric vehicle over time based on current state of charge data of the electric vehicle and the predicted energy consumption rate;
determining a time at which the projected state of charge will reach a threshold state of charge value; and
scheduling the at least one mobile charging station to charge the electric vehicle based on the time.

5. The method of claim 1, further comprising:
identifying charging patterns for the plurality of electric vehicles at the worksite based on historical charging data,
wherein generating the charging sequence is further based on the charging patterns.

6. The method of claim 1, further comprising:
simulating charge scheduling of the at least one mobile charging station and the plurality of electric vehicles for the worksite; and
generating a dataset of simulation results for the worksite, wherein the charging sequence is generated based at least in part on the dataset of simulation results.

7. The method of claim 1, further comprising:
determining routes for the at least one mobile charging station to reach respective locations of the plurality of electric vehicles based on the charging sequence.

8. A system comprising:
one or more processors; and
one or more memories storing instructions that, when executed by the one or more processors, cause the system to perform a process of managing electric vehicle charging, the process comprising:
receiving state of charge values for respective batteries of a plurality of electric vehicles at a worksite;
determining respective charging times required to charge the respective batteries to a threshold value based on the state of charge values;
calculating a charging capability of at least one mobile charging station at the worksite;
generating a charging sequence for the plurality of electric vehicles based on the respective charging times and the charging capability of the at least one mobile charging station; and
assigning the at least one mobile charging station to the charging sequence.

9. The system of claim 8, wherein the process further comprises:
sending a notification to the plurality of electric vehicles, wherein the notification includes, for each electric vehicle, a place in the charging sequence, a battery status, a battery temperature, and time remaining until requiring a charge.

10. The system of claim 8, wherein the process further comprises:
determining a charging rate of the at least one mobile charging station;
determining energy losses during charging operations of the at least one mobile charging station;
determining a current state of charge of the at least one mobile charging station; and
calculating the charging capability of the at least one mobile charging station based on the charging rate, the energy losses, and the current state of charge.

11. The system of claim 8, wherein the process further comprises:
inputting, into a machine learning model, historical usage data for an electric vehicle of the plurality of electric vehicles for a task being performed by the electric vehicle;
determining, by the machine learning model, a predicted energy consumption rate while the electric vehicle performs the task;
calculating, by the machine learning model, a projected state of charge for the electric vehicle over time based on current state of charge data of the electric vehicle and the predicted energy consumption rate;
determining a time at which the projected state of charge will reach a threshold state of charge value; and
scheduling the at least one mobile charging station to charge the electric vehicle based on the time.

12. The system of claim 8, wherein the process further comprises:
identifying charging patterns for the plurality of electric vehicles at the worksite based on historical charging data,
wherein generating the charging sequence is further based on the charging patterns.

13. The system of claim 8, wherein the process further comprises:
simulating charge scheduling of the at least one mobile charging station and the plurality of electric vehicles for the worksite; and
generating a dataset of simulation results for the worksite, wherein the charging sequence is generated based at least in part on the dataset of simulation results.

14. The system of claim 8, wherein the process further comprises:
determining routes for the at least one mobile charging station to reach respective locations of the plurality of electric vehicles based on the charging sequence.

15. A non-transitory computer-readable medium storing instructions that, when executed by a computing system, cause the computing system to perform operations of managing electric vehicle charging, the operations comprising:
receiving state of charge values for respective batteries of a plurality of electric vehicles at a worksite;
determining respective charging times required to charge the respective batteries to a threshold value based on the state of charge values;
calculating a charging capability of at least one mobile charging station at the worksite;
generating a charging sequence for the plurality of electric vehicles based on the respective charging times and the charging capability of the at least one mobile charging station; and
assigning the at least one mobile charging station to the charging sequence.

16. The non-transitory computer-readable medium of claim 15, wherein the operations further comprise:
sending a notification to the plurality of electric vehicles, wherein the notification includes, for each electric vehicle, a place in the charging sequence, a battery status, a battery temperature, and time remaining until requiring a charge.

17. The non-transitory computer-readable medium of claim 15, wherein the operations further comprise:
determining a charging rate of the at least one mobile charging station;
determining energy losses during charging operations of the at least one mobile charging station;
determining a current state of charge of the at least one mobile charging station; and
calculating the charging capability of the at least one mobile charging station based on the charging rate, the energy losses, and the current state of charge.

18. The non-transitory computer-readable medium of claim 15, wherein the operations further comprise:
inputting, into a machine learning model, historical usage data for an electric vehicle of the plurality of electric vehicles for a task being performed by the electric vehicle;
determining, by the machine learning model, a predicted energy consumption rate while the electric vehicle performs the task;
calculating, by the machine learning model, a projected state of charge for the electric vehicle over time based on current state of charge data of the electric vehicle and the predicted energy consumption rate;
determining a time at which the projected state of charge will reach a threshold state of charge value; and
scheduling the at least one mobile charging station to charge the electric vehicle based on the time.

19. The non-transitory computer-readable medium of claim 15, wherein the operations further comprise:
identifying charging patterns for the plurality of electric vehicles at the worksite based on historical charging data,
wherein generating the charging sequence is further based on the charging patterns.

20. The non-transitory computer-readable medium of claim 15, wherein the operations further comprise:
simulating charge scheduling of the at least one mobile charging station and the plurality of electric vehicles for the worksite; and
generating a dataset of simulation results for the worksite, wherein the charging sequence is generated based at least in part on the dataset of simulation results.
